(19) United States
(12) Patent Application Publication
(10) Pub. No.: US 2008/0013664 A1
(43) Pub. Date: Jan. 17, 2008

(54) PHASE ERROR MEASUREMENT CIRCUIT AND METHOD THEREOF

(75) Inventor: Ping-Ying Wang, Hsinchu City (TW)

Correspondence Address: THOMAS, KAYDEN, HORSTEMEYER & RISLEY, LLP, 600 GALLERIA PARKWAY, STE 1500, ATLANTA, GA, 30339, US

(73) Assignee: MEDIATEK INC., Hsin-Chu (TW)

(21) Appl. No.: 11/456,628

(22) Filed: Jul. 11, 2006

(51) Int. Cl. H03D 3/24

(52) U.S. Cl. 375/373

(57) ABSTRACT

A phase error measurement circuit and related method, and in particular a recyclable phase error measurement circuit and related method applied in a phase detector for calculating a phase error value is disclosed. A phase error measurement circuit for calculating a phase error value comprises: a multi-phase clock generator, a memory unit, and a counter. The multi-phase clock generator generates N clocks in different phases. The memory unit buffers a remainder part of the phase error value according to a phase error signal and the clocks generated from the multi-phase clock generator. The counter increments an integral part of the phase error value at each clock cycle.

### BACKGROUND OF THE INVENTION

1. Field of the Invention

The present invention relates to a phase error measurement circuit and related method, and in particular relates to a recyclable phase error measurement circuit and related method applied in a phase detector.

2. Description of the Related Art

FIG. 1 shows a block diagram of a digital phase locked loop (DPLL) 100. The DPLL 100 comprises a digital phase detector 110, a digital gain multiplier 120, a digital delta-sigma modulator 130, digital-to-time converters 140 and 150, an integral charge pump 160, a bias generator 170, a proportional charge pump 180, and a voltage controlled oscillator (VCO) 190. The digital phase detector 110 detects the phase difference between a Non-Return to Zero (NRZ) data stream and a feedback clock and generates a phase error value ERRPD. The digital-to-time converter 140 generates an “iup” or “idn” integral control signal based on whether the feedback clock is lagging or leading the NRZ data stream. If the integral charge pump 160 receives the integral up control signal “iup”, current is driven into the bias generator 170; Otherwise, if the integral charge pump 160 receives the integral down control signal “idn”, current is drawn from the bias generator 170. Similarly, a “pup” or “pdn” proportional control signal is generated based on whether the feedback clock is lagging or leading the NRZ data stream according to the phase error value ERRPD. The bias generator 170 converts signals to a control voltage VBN that is used to tune the VCO 190. Based on the control voltages VBN and VBP, the VCO 190 oscillates at a higher or lower frequency, which affects the phase and frequency of the feedback clock. The VCO 190 stabilizes once the feedback clock follows the phase and frequency of the NRZ data stream.

FIG. 2 shows a block diagram of the digital phase detector 110 shown in FIG. 1. The digital phase detector 110 comprises a phase frequency detector (PFD) 210 and a phase error measurement circuit 220. The PFD 210 outputs up and down signals to the phase error measurement circuit 220. The phase error measurement circuit 220 counts the up or down signal to generate the phase error value ERRPD. The operation and architecture of the phase error measurement circuit 220 is simple, however, in order to cover a wide range of phase error, the phase error measurement circuit 220 requires a great number of delay flip-flops (DFFs) and delay units. The cost and complexity for implementing the digital phase detector are therefore increased.

### BRIEF SUMMARY OF THE INVENTION

A phase error measurement circuit for calculating a phase error value comprises a multi-phase clock generator, a memory unit, and a counter. The multi-phase clock generator generates N clocks in different phases. The memory unit buffers a remainder part of the phase error value according to a phase error signal and the clocks generated from the multi-phase clock generator. The counter increments an integral part of the phase error value at each clock cycle.

### BRIEF DESCRIPTION OF THE DRAWINGS

The present invention can be more fully understood by reading the subsequent detailed description and examples with references made to the accompanying drawings, wherein:

FIG. 1 shows a block diagram of a digital phase locked loop;

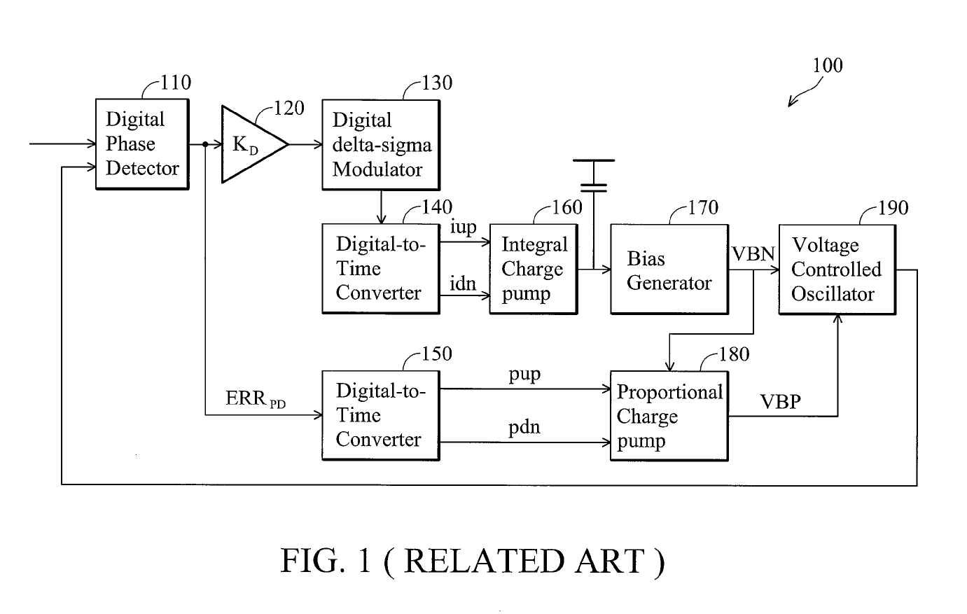

FIG. 2 shows a block diagram of the digital phase detector shown in FIG. 1;

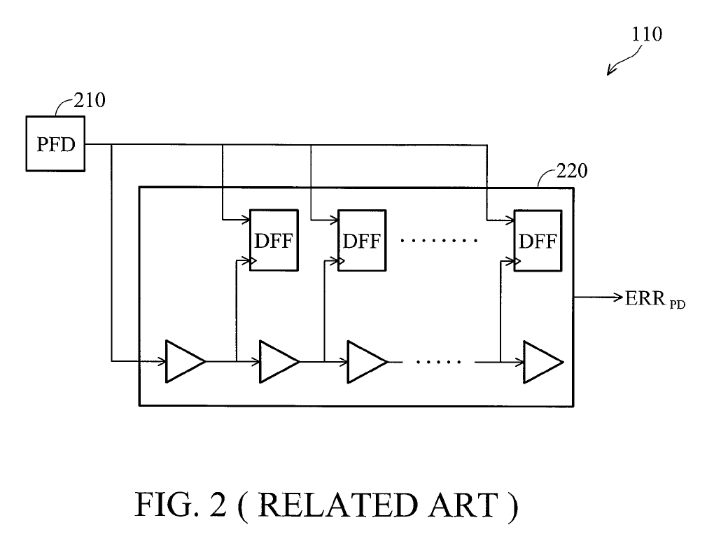

FIG. 3 shows a block diagram of a phase error measurement circuit applied in a digital phase detector according to a first embodiment of the invention;

FIG. 4 shows a timing diagram illustrating the operation of the phase error measurement circuit shown in FIG. 3;

FIG. 5 shows a block diagram of a phase error measurement circuit applied in a digital phase detector according to a second embodiment of the invention;

FIG. 6 shows a timing diagram illustrating the operation of the phase error measurement shown in FIG. 5;

FIG. 7 shows a block diagram of a phase error measurement circuit applied in a digital phase detector according to a third embodiment of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

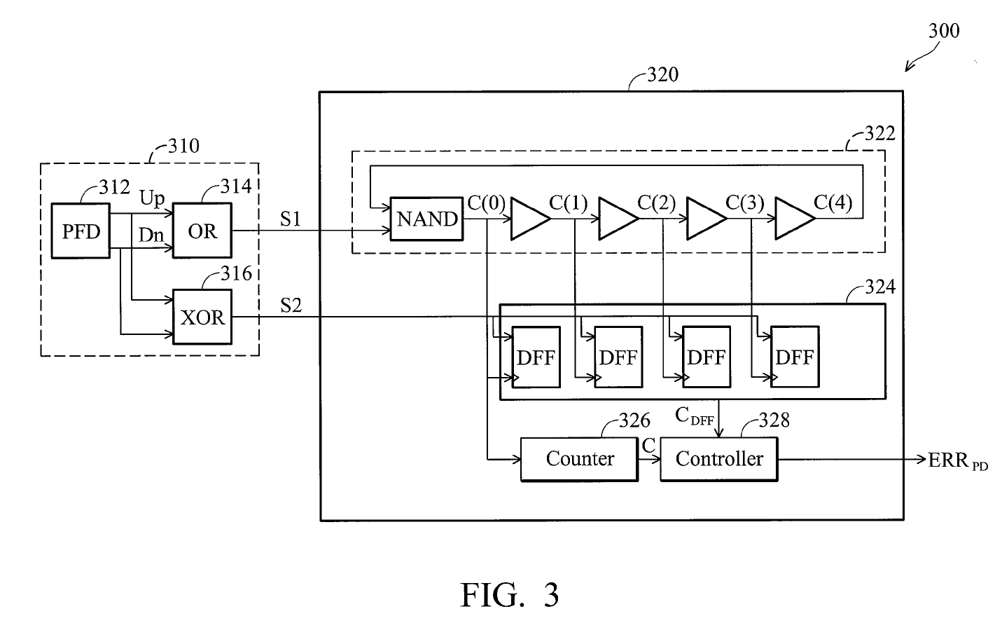

FIG. 3 shows a block diagram of a digital phase detector 300 according to a first embodiment of the invention. The digital phase detector 300 comprises a phase: frequency detector (PFD) module 310 and a phase error measurement circuit 320. The PFD module 310 comprises a PFD 312, an OR gate 314, and a XOR gate 316. The PFD 312 generates up signal Up or down signal Dn by comparing two input signals. The OR gate. 314 generates an enabling signal S1 to enable the operation of the phase error measurement circuit 320. The XOR gate 316 generates a phase error signal S2 for the phase error measurement circuit 320. A detailed description of the phase error measurement circuit 320 is provided in the following.

The phase error measurement circuit 320 comprises a multi-phase clock generator 322, a memory unit 324, a counter 326, and a controller 328. The multi-phase clock generator 322 comprises a plurality of inverters for providing count clocks C(0)˜C(4) in different phases. The memory unit 324 comprises a plurality of DFFs. The count clocks C(0)˜C(4) control the enablement of the DFFs, and the phase error signal S2 are latched by the according to the count clocks C(0)˜C(4). The period T of the count clock is equal to the loop delay time N*T_{d} (T_{d} is the time delayed by a delay unit and N is the number of inverters). Taking T=4T_{d} (4 delay units) as an example, the count data C_{DFF} (the remainder of diving the phase error value ERR_{PD} by 4) of the DFFs is reported to the controller 328, and the count value C (the integral part of the phase error value ERR_{PD}) of the counter 326 accumulates the number of clock period T. The controller 328 reads the count value C and data in the DFFs to calculate the phase error value ERR_{PD}. The phase error value ERR_{PD} is calculated according to the following formula:

ERR_{PD}=C*N+C_{DFF}

In the case of four delay units and four DFFs (N=4), some examples of calculating the phase error value ERR_{PD} are provided in the following.

If the values stored in the DFFs are 0000 and the count value C is equal to 8, then the phase error value ERR_{PD} is equal to 32 (8*4+0). If the values stored in the DFFs are 1000 and the count value C is equal to 8, then the phase error value ERR_{PD} is equal to 33 (8*4+1).

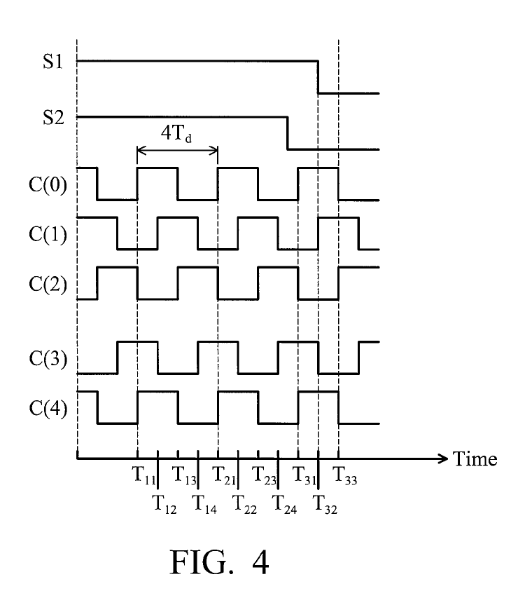

Please refer to FIG. 3 and FIG. 4. FIG. 4 shows a timing diagram illustrating the operation of the phase error measurement circuit 320 shown in FIG. 3. The enabling signal S1 enables the operation of the multi-phase clock generator 322. The count data C_{DFF} of the DFFs is updated at the rising edge of each clock, and the count value C of the counter 326 is incremented every clock period T (T=4T_{d}). At times T₁₁, T₁₂, T₁₃, and T₁₄, the first, second, third, and fourth DFFs are updated, respectively. For example, the output of the plurality of DFFs is equal to 1000 at time T₁₁, 1100 at time T₁₂, 1110 at time T₁₃, 1111 at time T₁₄. At times T₁₁, T₂₁, and T₃₁, the count value C of the counter 326 is incremented. For example, the count value C is equal to 1 at time T₁₁, 2 at time T₂₁, and 3 at time T₃₁. Compared with conventional phase error detectors, the phase error measurement circuit 320 does not require a great number of delay flip-flops (DFF) and delay units. However, the multi-phase clock generator 322 may operate abnormally resulting in an incorrect calculation. A detailed description is provided in the following.

For example, assume that the enabling signal S1 converts from high to low at time T32 to disable the operation of the multi-phase clock generator 322. It can be observed that multi-phase clock generator 322 needs at least the duration longer than the loop delay time 4Td to stabilize since it is a kind of ring oscillator. The enabling signal S1, however, is converted from high to low before the multi-phase clock generator 322 stabilizes (the multi-phase clock generator 322 stabilizes at time T₃₃). In other words, multi-phase clock generator 322 will operate abnormally resulting in an incorrect calculation of the phase error measurement circuit 320.

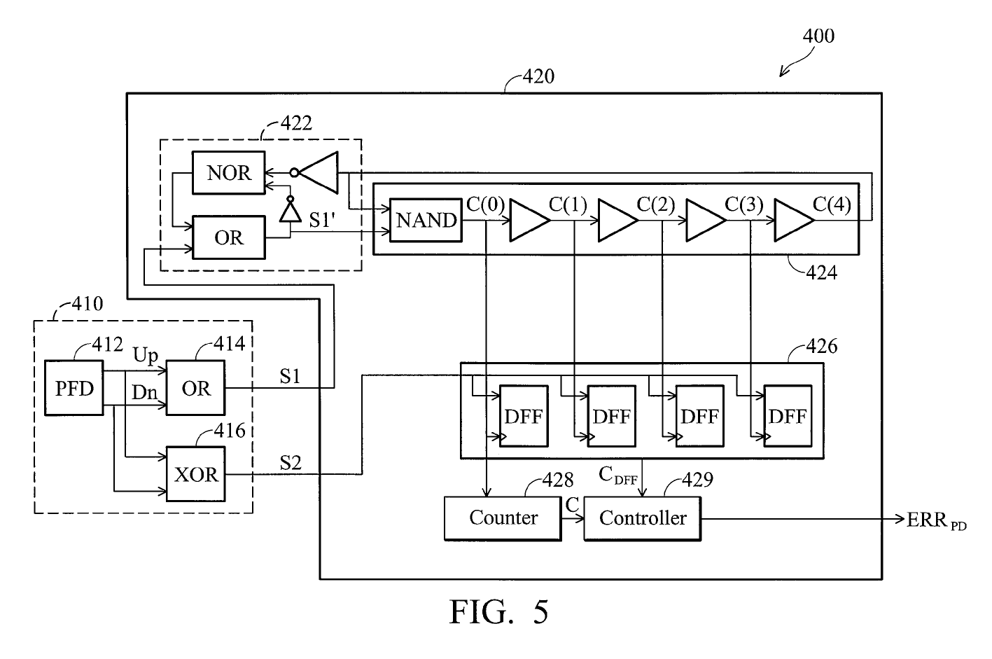

FIG. 5 shows a block diagram of a digital phase detector 400 according to a second embodiment of the invention. The digital phase detector 400 comprises a PFD module 410 and a phase error measurement circuit 420. Similarly, the PFD module 410 generates an enabling signal S1 for enabling the operation of the phase error measurement circuit 420, and a phase error signal S2 for the phase error measurement circuit 420. The phase error measurement circuit 420 comprises a phase extension unit 422, a multi-phase clock generator 424, a memory unit 426, a counter 428, and a controller 429. Compared with the first embodiment, the difference is that the phase error measurement circuit 420 further comprises the phase extension unit 422 to solve the above-mentioned glitch problem of FIG. 4. The phase extension unit 422 comprises a NOR gate, an OR gate, and two inverters. Under the operation of these gates, the enabling signal S1 is feed to the phase extension unit 422 to generate an enabling signal S1′. When the enabling signal S1 is converted from high to low to disable the operation of the multi-phase clock generator 424, the enabling signal S1′ is not converted from high to low immediately. The enabling signal S1′ waits until the multi-phase clock generator 424 stabilizes. In other words, the enabling signal S1′ is converted from high to low when the multi-phase clock generator 424 stabilizes.

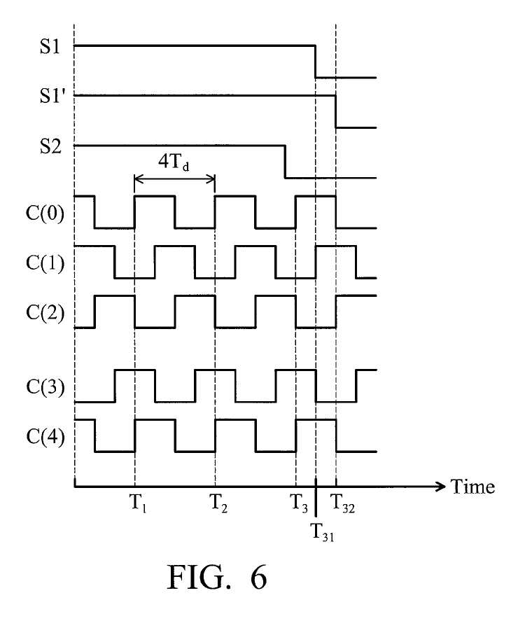

Please refer to FIG. 6 with reference to FIG. 5. FIG. 6 shows a timing diagram illustrating the operation of the phase error measurement 420 shown in FIG. 5. Compared with the first embodiment, the enabling signal S1′ is utilized as the input of the multi-phase clock generator 424. As shown in FIG. 6, the enabling signal S1 converts from high to low at time T₃₁. The phase extension unit 422 holds the high status of the enabling signal S1 until time T₃₂. In other words, the enabling signal S1′ enables the operation of the multi-phase clock generator 424 in the beginning, and disables the operation at time T₃₂ when the multi-phase clock generator 424 stabilizes.

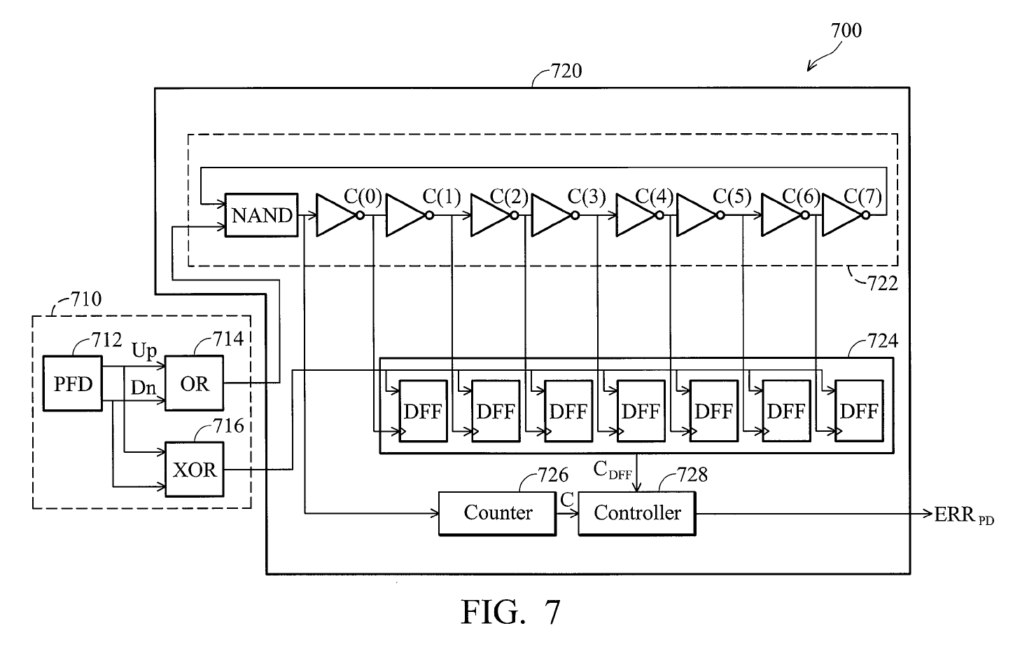

FIG. 7 shows a block diagram of a digital phase detector 700 according to a third embodiment of the invention. The digital phase detector 700 comprises a phase frequency detector (PFD) module 710 and a phase error measurement circuit 720. The phase error measurement circuit 720 comprises a multi-phase clock generator 722, a memory unit 724, a counter 726, and a controller 728. Compared with the multi-phase clock generator 322 in the first embodiment, the multi-phase clock generator 722 in this embodiment comprises a plurality of inverters. Because the operation of the third embodiment is similar to that of the first embodiment, further discussion of it is omitted for the sake of brevity.

Various embodiments of the phase error measurement circuit of the invention implement the recycle concept to reduce the number of DFFs and delay units. The phase detectors employing the recyclable phase error measurement circuit achieve the flexibility by using only a small number of delay cells, which is highly useful for detecting an unknown range of phase error. In other words, the hardware space and cost required for realizing phase error measurement circuit can be reduced. Additionally, a phase extension unit cooperated with the phase error measurement circuit is capable of avoiding the abnormal operation in some situations.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass a PFD module 310, and a phase error measurement circuit 220.

What is claimed is:

1. A phase error measurement circuit for calculating a phase error value, comprising:
a multi-phase clock generator for generating N clocks in different phases with the same frequency;
a memory unit controlled by the clocks generated from the multi-phase clock generator for latching a remainder part of the phase error value according to a phase error signal; and
a counter coupled to the multi-phase clock generator for counting an integral part of the phase error value by incrementing the counter at each cycle of a clock generated by the multi-phase clock generator according to the phase error signal.

2. The phase error measurement circuit as claimed in claim 1 further comprises a controller coupled to the memory unit and the counter for generating the phase error value according to the following formula:
ERR_{PD}=C₁*N+C₂
Wherein ERRPD is the phase error value, C₂ is the remainder part of the phase error value, and C₁ is the integral part of the phase error value.

3. The phase error measurement circuit as claimed in claim 1, wherein the multi-phase clock generator further comprises:
a plurality of delay units connected in series for generating the N clocks; and
a NAND gate outputting to the first buffer by receiving an enabling signal and an Nth clock.

4. The phase error measurement circuit as claimed in claim 3, wherein the memory unit further comprises:
a plurality of delay buffers connected in series and respectively coupled to the delay units for receiving the phase error signal, the clock generated from each delay unit clocks a corresponding delay buffer.

5. The phase error measurement circuit as claimed in claim 4 further comprises a phase extension unit coupled to the multi-phase clock generator for postponing a transition in the enabling signal until the multi-phase clock generator enters a stable state.

6. The phase error measurement circuit as claimed in claim 1 further comprises a phase frequency detector (PFD) module coupled to the memory unit and the multi-phase clock generator for generating an enabling signal for the multi-phase clock generator, and the phase error signal for the memory unit.

7. The phase error measurement circuit as claimed in claim 6, wherein the PFD module further comprises:
a PFD for generating an up signal or a down signal by comparing two input signals;
an OR gate coupled to the PFD for receiving the up and down signals to generate the enabling signal; and
an XOR gate coupled to the PFD for receiving the up and down signals to generate the phase error signal.

8. The phase error measurement circuit as claimed in claim 1, wherein the multi-phase clock generator further comprises:
a plurality of inverters connected in series for generating the N clocks; and
a NAND gate outputting to the first inverters by receiving an enabling signal and an Nth clock.

9. The phase error measurement circuit as claimed in claim 8, wherein the memory unit further comprises:
a plurality of delay buffers connected in series and respectively coupled to the inverters for receiving the phase error signal, the clock generated from each delay unit clocks a corresponding delay buffer.

10. A method for calculating a phase error value, the method comprising:
generating N clocks in N different phases with the same frequency;
updating a remainder part of the phase error value at each cycle of each clock according to a phase error signal; and
counting an integral part of the phase error value by incrementing at each cycle of a clock according to the phase error signal.

11. The phase error measurement circuit as claimed in claim 10, wherein the phase error value is calculated according to the following formula:
ERR_{PD}=C₁*N+C₂
Wherein ERR_{PD} is the phase error value, C₂ is the remainder part of the phase error value, and C₁ is the integral part of the phase error value.

12. The phase error measurement circuit as claimed in claim 10, wherein the step of generating N clocks further comprises:
receiving an enabling signal for enabling the operation of generating N clocks.

13. The phase error measurement circuit as claimed in claim 12, wherein a transition in the enabling signal is postponed until the operation of generating N clocks becomes stable.
